(19) United States
(12) Patent Application Publication
(10) Pub. No.: US 2025/0350245 A1
(43) Pub. Date: Nov. 13, 2025

(54) RADIO FREQUENCY SYSTEM

(71) Applicant: Silergy Technology, Santa Clara, CA (US)

(72) Inventor: Wei Chen, Shanghai (CN)

(21) Appl. No.: 19/176,248

(22) Filed: Apr. 11, 2025

Related U.S. Application Data
(60) Provisional application No. 63/643,990, filed on May 8, 2024.

(51) Int. Cl. H03F 1/02; H03F 3/24

(52) U.S. Cl. CPC H03F 1/0227; H03F 3/245; H03F 2200/102; H03F 2200/451

(57) ABSTRACT

A radio frequency system can include: a voltage regulator configured to generate a DC voltage signal; a power amplifying module configured to receive an input radio frequency signal, the DC voltage signal as a supply voltage, and to generate an amplified voltage signal by amplifying the input radio frequency signal; and a controller configured to regulate the DC voltage signal in accordance with a reference signal representing the input radio frequency signal, in order to decrease a power loss of the power amplifying module.

### RELATED APPLICATIONS

This application claims the benefit of U.S. Provisional Patent Application No. 63/643,990, filed on May 8, 2024, which is incorporated herein by reference in its entirety.

### FIELD OF THE INVENTION

The present invention generally relates to the field of semiconductor technology, and more particularly to radio frequency systems, circuits, and methods of operation.

### BACKGROUND

Radio frequency amplifiers are widely employed in the fields of AM broadcast transmitter and cellular communication systems, and particularly in smartphones. For most application systems using radio frequency amplifiers, the efficiency of the amplifier plays important roles of design, operation, and efficiency of the full system. Power supply requirements, RF amplifying performance, and heat dissipation can all be influenced by the efficiency. However, with the increase of battery applications (e.g., smartphones, mobile devices, etc.), power loss of batteries in battery-powered systems is of major concern. For radio frequency amplifiers, efficiency is the ratio between output power and DC input power, so the supply voltage of the radio frequency amplifier has a relatively large impact on efficiency.

### BRIEF DESCRIPTION OF THE DRAWINGS

FIG. 1 is a schematic diagram of a first example radio frequency system, in accordance with embodiments of the present invention.

FIG. 2 is a schematic diagram of a first example pin arrangement of the radio frequency system in the first example, in accordance with embodiments of the present invention.

FIG. 3 is a schematic diagram of a second example pin arrangement of the radio frequency system in the first example, in accordance with embodiments of the present invention.

FIG. 4 is a schematic diagram of a second example radio frequency system, in accordance with embodiments of the present invention.

FIG. 5 is a waveform diagram of example operation of radio frequency system, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

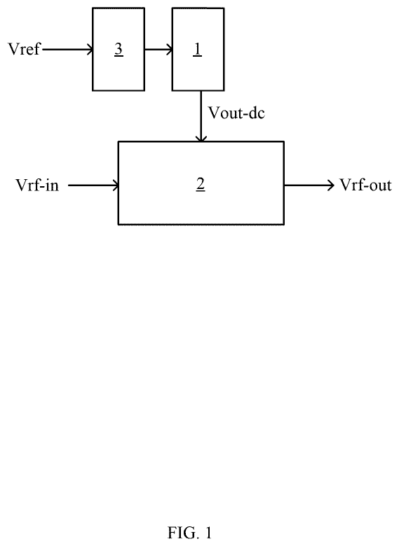

Referring now to FIG. 1, shown is a schematic diagram of a first example radio frequency system in accordance with embodiments of the present invention. The example radio frequency system can include voltage regulator 1, power amplifying module 2, and controller 3. Voltage regulator 1 can generate DC voltage signal Vout-dc. power amplifying module 2 may receive DC voltage signal Vout-dc as a supply voltage thereof and input radio frequency signal Vrf-in, and can amplify input radio frequency signal Vrf-in under the action of the supply voltage, in order to generate amplified voltage signal Vrf-out. Amplified voltage signal Vrf-out may be provided to a load, such as an antenna.

Controller 3 may receive reference signal Vref characterizing information of input radio frequency signal Vrf-in, and can adjust DC voltage signal Vout-dc according to reference signal Vref. For example, reference signal Vref can characterize the amplitude of input radio frequency signal Vrf-in. Therefore, voltage regulator 1 may adaptively adjust the supply voltage of power amplifying module 2 according to reference signal Vref, thereby reducing the power loss of the power amplifying module and improving the efficiency.

In one embodiment, voltage regulator 1 can adaptively adjust DC voltage signal Vout-dc according to reference signal Vref, such that voltage signal Vout-dc has a same trend as that of amplified voltage signal Vrf-out, thereby reducing losses and improving efficiency. In one embodiment, DC voltage signal Vout-dc may be adjusted to reduce the error between DC voltage signal Vout-dc and amplified voltage signal Vrf-out, in order to reduce power loss and improve efficiency. In one embodiment, power amplifying module 2 can include a power amplifier, and the drain efficiency of the power amplifier can be expressed as follows in Equation (1).

η=Pₒᵤₜ/P_{DC}=I₁V₁/I_{dc}V_{out-dc}(1)

Here, I1 is the amplitude of the fundamental component of the output current, V1 is the amplitude of the fundamental component of the amplified voltage signal, Idc is the drain current of the power amplifier, and Vout-dc is the supply voltage of the power amplifier. In particular embodiments, the supply voltage of the power amplifier may have the same variation trend as that of amplified voltage signal Vrf-out. That is, amplified V1 may have the same variation trend as DC voltage signal Vout-dc, which can improve the drain efficiency. In some approaches, in order to maintain a normal operation state of the power amplifying module, the output voltage of the voltage regulator may be fixed and higher than the maximum amplitude of the output voltage of the power amplifying module. In this way, the power loss of the power amplifying module may be much higher, thereby reducing the efficiency of the power amplifying module.

In particular embodiments, when the power amplifying module is in a normal operation mode, the DC voltage signal Vout-dc can be controlled to have a same variation trend as the amplitude of amplified voltage signal Vrf-out. Therefore, when the amplitude of amplified voltage signal Vrf-out increases, DC voltage signal Vout-dc can also be controlled to correspondingly increase. Similarly, when the amplitude of amplified voltage signal Vrf-out decreases, DC voltage signal Vout-dc can also be controlled to correspondingly decrease. When the power amplifying module is in a standby mode, DC voltage signal Vout-dc can be controlled to be approximately a threshold voltage, in order to maintain the normal operation of the power amplifying module, and thereby reducing power loss.

In particular embodiments, the voltage regulator may be configured as an isolation voltage regulator or a non-isolation voltage regulator. For example, the voltage regulator may be any suitable converter topology (e.g., buck, boost, buck-boost, flyback voltage regulator, etc.). In another example, the voltage regulator can be a multiphase voltage regulator for supplying multiple supply voltages to each power amplifier separately.

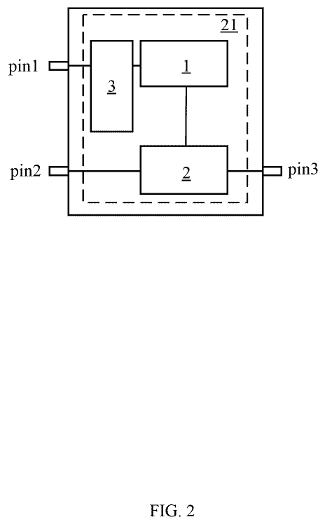

Referring now to FIG. 2, shown is a schematic diagram of a first example pin arrangement of the radio frequency system in the first example, in accordance with embodiments of the present invention. The radio frequency system shown in this particular example can be integrated into one chip, which can include first pin ‘pin1’for receiving reference signal Vref, second pin ‘pin2’ for receiving input radio frequency signal Vrf-in, and third pin ‘pin3’for outputting amplified voltage signal Vrf-out. In one particular packaging application, voltage regulator 1, power amplifier module 2, and controller 3 can be packaged in die 21.

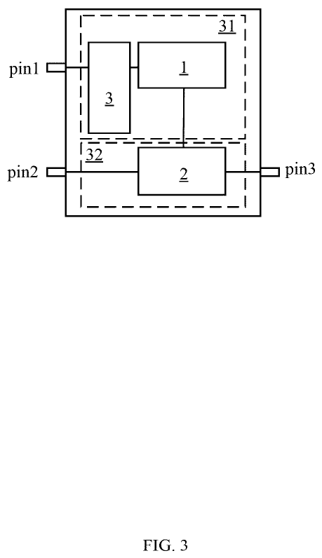

Referring now to FIG. 3, shown is a schematic diagram of a second example pin arrangement of the radio frequency system in the first example, in accordance with embodiments of the present invention. In this particular example, the radio frequency system may utilize two dies for packaging. Voltage regulator 1 and controller 3 can be packaged in die 31, and power amplifying module 2 may be packaged in die 32. Further, this example may utilize packaging technology to package dies 31 and 32 in the same housing, in order to protect dies 31 and 32 from interference or damage from the external environment.

It should be understood that in particular embodiments, the die can utilize an appropriate packaging form according to the application scenario and environment, such as DSP (dual in-line package), QFP (quad flat package, square flat package) or BGA (ball grid array, ball grid array package), as well as the corresponding packaging material (e.g., plastic, ceramic, metal materials, etc.).

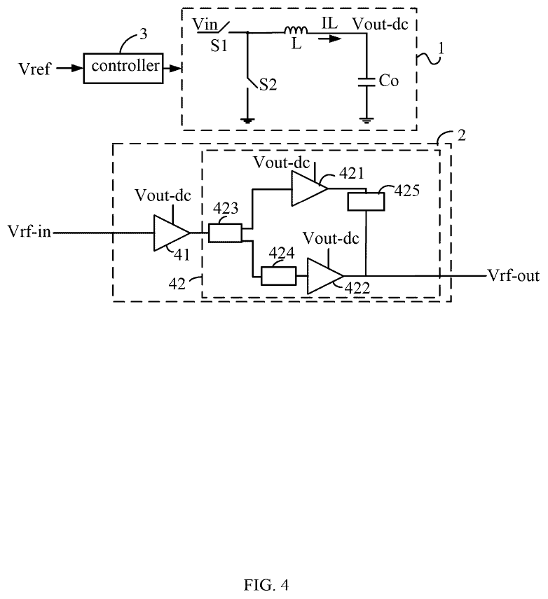

Referring now to FIG. 4, shown is a second example radio frequency system in accordance with embodiments of the present invention. In this particular example, the radio frequency system can include voltage regulator 1, power amplifying module 2, and controller 3. In FIG. 4, voltage regulator 1 can be a buck voltage regulator, including power transistors S1 and S2, inductor L, and output capacitor Co. Power transistors S1 and S2 can connect in series, one end of inductor L can connect to a common connection point of power transistors S1 and S2, and the other end of inductor L can connect to output capacitor Co, such that DC voltage signal Vout-dc can be generated at both ends of output capacitor Co. Controller 3 may receive reference signal Vref, and can generate a driving signal for controlling power transistors S1 and S2 to be turned on and off.

In particular embodiments, reference signal Vref can be an envelope signal, which can be generated by a radio frequency transceiver in the radio frequency system and may characterize the amplitude of the input radio frequency signal. Since amplified voltage signal Vrf-out can be generated by amplifying the input radio frequency signal, controller 3 may adjust DC voltage signal Vout-dc according to the envelope signal, and the DC voltage signal and amplified voltage signal Vrf-out can be controlled to have the same change trend. In one example, the DC voltage signal can be consistent with (e.g., the same as or positively correlated therewith) the amplitude of amplified voltage signal Vrf-out. Also for example, the duty cycle of the conduction time of power transistors S1 and S2 can be adjusted by the driving signal, in order to adaptively adjust DC voltage signal Vout-dc.

In particular embodiments, power amplifying module 2 can include first-stage amplifying unit 41 and second-stage amplifying unit 42. First amplifying unit 41 may perform a first amplification process on input radio frequency signal Vrf-in as a preamplifier. Second-stage amplifying unit 42 may receive the output signal of first-stage amplifying unit 41 and perform a second amplification process thereon, in order to generate amplified voltage signal Vrf-out. Second-stage amplifying unit 42 can include carrier power amplifier 421 and peak power amplifier 422, which may form an amplification module with a Doherty architecture.

In particular embodiments, first-stage amplifying unit 410 may receive DC voltage signal Vout-dc as the supply voltage. Carrier power amplifier 421 and peak power amplifier 422 can respectively be coupled in series with first-stage amplifying unit 410. In one example, carrier power amplifier 421 and peak power amplifier 422 may both receive DC voltage signal Vout-dc as the supply voltage. In another example, the phase of the supply voltage of carrier power amplifier unit 421 and peak power amplifier unit 422 may have an offset with the supply voltage of first-stage amplifying unit 410, such that the supply voltage of each amplifier can better follow amplified voltage signal Vrf-out.

In one example, a wavelength transmission line can connect in series between DC voltage signal Vout-dc and the supply voltages of carrier power amplifier 421 and peak power amplifier 422, such that the supply voltages of carrier power amplifier 421 and peak power amplifier 422 have an offset from the phase of DC voltage signal Vout-dc.

In another example, first-stage amplifying unit 410, carrier power amplifier 421, and peak power amplifier 422 can be powered by three different voltage regulators. Each voltage regulator can generate independent DC voltage signal as the supply voltage for one of the three amplifiers. Therefore, when there are many amplifiers, the supply voltages of all amplifiers can be the same and provided by DC voltage signal Vout-dc, or the supply voltage of each amplifier can be provided by an independent voltage regulator.

In particular embodiments, second-stage amplifying unit 42 can also include power divider 423, and wavelength transmission lines 424 and 425. Power divider 423 can divide the received input signal into two input signals of the power amplifier branches at the input end of the second-stage amplifying unit. Wavelength transmission line 424 can adjust the phase difference, and wavelength transmission line 425 can adjust the output impedance of carrier amplifier 421.

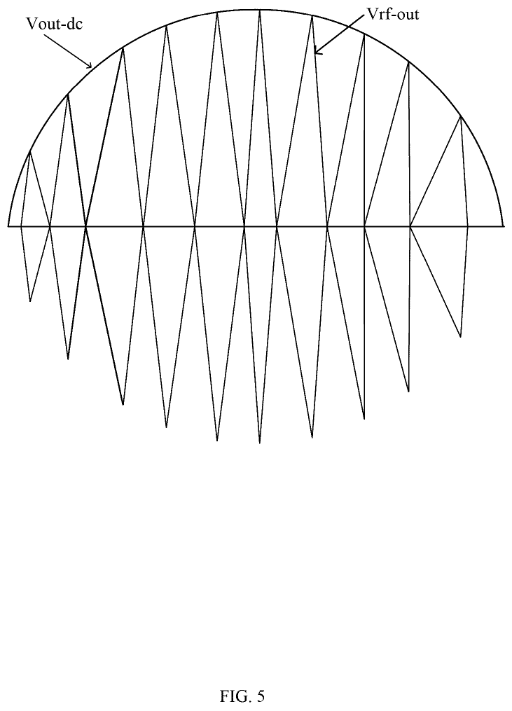

Referring now to FIG. 5, shown is a waveform diagram of example operation of radio frequency system, in accordance with embodiments of the present invention. In this particular example, the controller may receive an envelope signal as the reference signal, and can control the voltage regulator to generate amplified voltage signal Vrf-out that follows the forward envelope of the input radio frequency signal, such that the change trend of DC voltage signal Vout-dc is the same as that of the amplitude of amplified voltage signal Vrf-out. Further, the DC voltage signal can be consistent with the amplitude of amplified voltage signal Vrf-out. As shown, in order to improve efficiency, DC voltage signal Vout-dc can be adjusted in real time to follow the amplitude of amplified voltage signal Vrf-out. The change degree of DC voltage signal Vout-dc may be the same as that of the amplitude of amplified voltage signal Vrf-out. That is, if the amplitude of amplified voltage signal Vrf-out is increased by a first value, DC voltage signal Vout-dc can also be increased by the first value.

In particular embodiments, within the time interval between two adjacent transmitting pulses of the input radio frequency signal, DC voltage signal Vout-dc can be adjusted accordingly to match the amplitude of the subsequent amplified voltage signal. Also, DC voltage signal Vout-dc can be adjusted in advance to ensure that the supply voltage provided by the voltage regulator to the power amplifying module is a voltage that the power amplifying module may operate in a higher efficiency mode.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A radio frequency system, comprising:
a) a voltage regulator configured to generate a DC voltage signal;
b) a power amplifying module configured to receive an input radio frequency signal, the DC voltage signal as a supply voltage, and to generate an amplified voltage signal by amplifying the input radio frequency signal; and
c) a controller configured to regulate the DC voltage signal in accordance with a reference signal representing the input radio frequency signal, in order to decrease a power loss of the power amplifying module.

2. The radio frequency system of claim 1, wherein the radio frequency system is integrated into a chip that is configured to receive the reference signal via a first pin, to receive the input radio frequency signal via a second pin, and to transmit the amplified voltage signal to a load via a third pin.

3. The radio frequency system of claim 2, wherein the power amplifying module, the controller, and the voltage regulator are integrated in one die.

4. The radio frequency system of claim 2, wherein the power amplifying module is integrated in a first die, the controller and the voltage regulator are integrated in a second die, and the first and second dies are packaged in one package.

5. The radio frequency system of claim 1, wherein the controller is configured to receive an envelope signal as the reference signal.

6. The radio frequency system of claim 5, wherein the controller is configured to regulate a duty cycle of a conduction time of a transistor in the voltage regulator in accordance with the envelope signal, in order to regulate the DC voltage signal.

7. The radio frequency system of claim 1, wherein the DC voltage signal is the same as that of an amplitude of the amplified voltage signal when the power amplifying module is in an operation mode.

8. The radio frequency system of claim 7, wherein the DC voltage signal is controlled to be consistent with the amplitude of the amplified voltage signal.

9. The radio frequency system of claim 7, wherein during a time interval between two adjacent transmitting pulses of the input radio frequency signal, the DC voltage signal is regulated correspondingly to match the following amplitude of the amplified voltage signal.

10. The radio frequency system of claim 1, wherein when the power amplifying module is in a standby mode, the DC voltage signal is controlled to be approximate with a threshold voltage to maintain the power amplifying module to decrease the power loss.

11. The radio frequency system of claim 1, wherein the voltage regulator is configured to be an isolated voltage regulator.

12. The radio frequency system of claim 1, wherein the voltage regulator is configured to be a non-isolated voltage isolator.

13. The radio frequency system of claim 1, wherein the voltage regulator is configured to be at least one of a buck, a boost, and a buck-boost voltage regulator.

14. The radio frequency system of claim 1, wherein the power amplifying module comprises a plurality of power amplifiers having a same supply voltage.

15. The radio frequency system of claim 14, wherein the same supply voltage that is provided to the plurality of power amplifiers is generated by at least one voltage regulator.

16. The radio frequency system of claim 1, wherein the power amplifying module comprises first and second power amplifiers coupled in series, a supply voltage of the first power amplifier is the DC voltage signal, and a supply voltage of the second power amplifier differs from the phase of the DC voltage signal by an offset.
